(19) United States
(12) Patent Application Publication
(10) Pub. No.: US 2025/0048880 A1
(43) Pub. Date: Feb. 6, 2025

(54) DISPLAY DEVICE AND MANUFACTURING METHOD THEREOF

(71) Applicant: Japan Display Inc., Tokyo (JP)

(72) Inventor: Nobuto MANAGAKI, Tokyo (JP)

(73) Assignee: Japan Display Inc., Tokyo (JP)

(21) Appl. No.: 18/775,347

(22) Filed: Jul. 17, 2024

(30) Foreign Application Priority Data
Jul. 31, 2023 (JP) 2023-124096

(51) Int. Cl. H10K 59/70; H10K 59/12; H10K 59/35

(52) U.S. Cl. CPC H10K 59/70; H10K 59/1201; H10K 59/353

(57) ABSTRACT

The display device includes at least one pixel having a first sub-pixel, a second sub-pixel, and a third sub-pixel. The first sub-pixel and the second sub-pixel respectively include red-emissive and green-emissive organic electroluminescence elements. The third sub-pixel includes a blue-emissive inorganic electroluminescence element. Each of the organic electroluminescence elements includes an anode, a cathode, and an organic electroluminescence layer between the anode and the cathode. The inorganic electroluminescence element includes an anode, a cathode, and an inorganic electroluminescence layer electrically connected to the anode and the cathode.

### CROSS-REFERENCE TO RELATED APPLICATIONS

This application claims the benefit of priority to Japanese Patent Application No. 2023-124096, filed on Jul. 31, 2023, the entire contents of which are incorporated herein by reference.

### FIELD

An embodiment of the present invention relates to a display device including a light-emitting element in a pixel and a manufacturing method thereof.

### BACKGROUND

In recent years, electroluminescence elements have been widely used in display devices and lighting devices. For example, in addition to display devices including an organic electroluminescence element (OLED) in each pixel, display devices and signage in which an inorganic electroluminescence element (LED) is arranged in each pixel are used in a variety of fields. Japanese Patent Application Publication No. 2018-106823 discloses that a display device with high color reproducibility can be provided by constructing a resonance structure in each organic electroluminescence element in a display device equipped with red-, green-, and blue-emissive organic light-emitting elements.

### SUMMARY

An embodiment of the present invention is a display device. The display device includes at least one pixel having a first sub-pixel, a second sub-pixel, and a third sub-pixel. The first sub-pixel and the second sub-pixel respectively include red-emissive and green-emissive organic electroluminescence elements. The third sub-pixel includes a blue-emissive inorganic electroluminescence element. Each of the organic electroluminescence elements includes an anode, a cathode, and an organic electroluminescence layer between the anode and the cathode. The inorganic electroluminescence element includes an anode, a cathode, and an inorganic electroluminescence layer electrically connected to the anode and the cathode.

An embodiment of the present invention is a manufacturing method of a display device. The manufacturing method includes: forming at least one pixel including a first sub-pixel, a second sub-pixel, and a third sub-pixel; respectively forming red-emissive and green-emissive organic electroluminescence elements in the first sub-pixel and the second sub-pixel; and forming a blue-emissive inorganic electroluminescence element in the third sub-pixel. Each of the organic electroluminescence elements has an anode, a cathode, and an organic electroluminescence layer between the anode and the cathode. The inorganic electroluminescence has an anode, a cathode, and an inorganic electroluminescence layer electrically connected to the anode and the cathode.

### BRIEF DESCRIPTION OF DRAWINGS

FIG. 1 is a schematic top view of a display device according to an embodiment of the present invention.

FIG. 2A is a schematic top view of a display device according to an embodiment of the present invention.

FIG. 2B is a schematic top view of a display device according to an embodiment of the present invention.

FIG. 3 is a schematic cross-sectional view of electroluminescence elements included in a display device according to an embodiment of the present invention.

FIG. 4A is a schematic cross-sectional view of an inorganic electroluminescence element included in a display device according to an embodiment of the present invention.

FIG. 4B is a cross-sectional view of an inorganic electroluminescence element included in a display device according to an embodiment of the present invention.

FIG. 5 is a schematic cross-sectional view of a display device according to an embodiment of the present invention.

FIG. 6 is a schematic cross-sectional view of a display device according to an embodiment of the present invention.

FIG. 7 is a schematic cross-sectional view of a display device according to an embodiment of the present invention.

FIG. 8A is a schematic top view of a display device according to an embodiment of the present invention.

FIG. 8B is a schematic top view of a display device according to an embodiment of the present invention.

FIG. 9 is a schematic top view of a display device according to an embodiment of the present invention.

FIG. 10 is a schematic cross-sectional view of a display device according to an embodiment of the present invention.

FIG. 11A is a schematic view showing a relationship between a structure of a light-emitting element and current efficiency.

FIG. 11B is a schematic view showing a relationship between a structure of a light-emitting element and current efficiency.

FIG. 12A is a schematic view showing a relationship between a structure of a light-emitting element and current efficiency.

FIG. 12B is a schematic view showing a relationship between a structure of a light-emitting element and current efficiency.

FIG. 13 is a schematic cross-sectional view showing a manufacturing method of a display device according to an embodiment of the present invention.

FIG. 14 is a schematic cross-sectional view showing a manufacturing method of a display device according to an embodiment of the present invention.

FIG. 15 is a schematic cross-sectional view showing a manufacturing method of a display device according to an embodiment of the present invention.

FIG. 16 is a schematic cross-sectional view showing a manufacturing method of a display device according to an embodiment of the present invention.

FIG. 17 is a schematic cross-sectional view showing a manufacturing method of a display device according to an embodiment of the present invention.

FIG. 18 is a schematic cross-sectional view showing a manufacturing method of a display device according to an embodiment of the present invention.

FIG. 19 is a schematic cross-sectional view showing a manufacturing method of a display device according to an embodiment of the present invention.

FIG. 20 is a schematic cross-sectional view showing a manufacturing method of a display device according to an embodiment of the present invention.

FIG. 21 is a schematic cross-sectional view showing a manufacturing method of a display device according to an embodiment of the present invention.

FIG. 22 is a schematic cross-sectional view showing a manufacturing method of a display device according to an embodiment of the present invention.

FIG. 23 is a schematic cross-sectional view showing a manufacturing method of a display device according to an embodiment of the present invention.

FIG. 24 is a schematic cross-sectional view showing a manufacturing method of a display device according to an embodiment of the present invention.

FIG. 25 is a schematic cross-sectional view showing a manufacturing method of a display device according to an embodiment of the present invention.

### DESCRIPTION OF EMBODIMENTS

Hereinafter, each embodiment of the present invention is explained with reference to the drawings. The invention can be implemented in a variety of different modes within its concept and should not be interpreted only within the disclosure of the embodiments exemplified below.

The drawings may be illustrated so that the width, thickness, shape, and the like are illustrated more schematically compared with those of the actual modes in order to provide a clearer explanation. However, they are only an example, and do not limit the interpretation of the invention. In the specification and the drawings, the same reference number is provided to an element that is the same as that which appears in preceding drawings, and a detailed explanation may be omitted.

In the present invention, when a plurality of films is formed by performing etching or photoirradiation on one film, the plurality of films may have different functions and roles. However, the plurality of films originates from a film fabricated by the same process as the same layer and has the same layer structure and the same material. Hence, the plurality of films is defined as existing in the same layer.

In the specification and the claims, unless specifically stated, when a state is expressed where a structure is arranged “over” another structure, such an expression includes both a case where a structure is arranged immediately above the “other structure” so as to be in contact with the “other structure” and a case where the structure is arranged over the “other structure” with an additional structure therebetween.

In the specification and the claims, an expression “a structure is exposed from another structure” means a mode in which a part of the structure is not covered by the other structure and includes a mode where the part uncovered by the other structure is further covered by another structure. In addition, the mode expressed by this expression includes a mode where the structure is not in contact with the other structure.

### 1. Overall Structure of Display Device

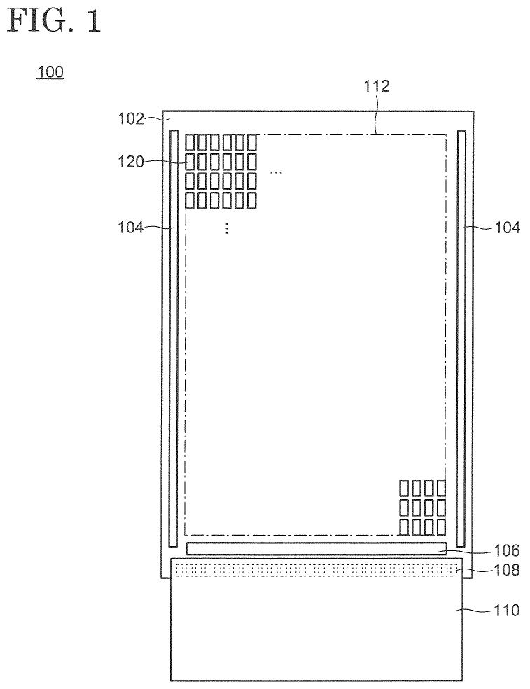

A schematic top view of a display device 100 according to an embodiment of the present invention is shown in FIG. 1. There is no restriction on the size of the display device 100. Thus, the display device 100 may be a small-sized display device used in mobile phones and smartphones or a medium-sized display device used in TVs and computer monitors, for example. Alternatively, the display device 100 may be a large-sized display device exemplified by an electronic bulletin board or signage.

As shown in FIG. 1, the display device 100 has a substrate 102 over which a variety of patterned insulating films, semiconductor films, and conductor films is stacked. Appropriate combination of these films allows the formation of a plurality of pixels 120 and driver circuits (scanning-line driver circuit 104 and signal-line driver circuit 106) for driving the pixels 120 over the substrate 102. A single region surrounding all of the plurality of pixels 120 is referred to as a display region 112, and the driver circuits are provided in a region outside of the display region 112 (frame region). A counter substrate which is not illustrated is provided over the pixels 120, the scanning-line driver circuit 104, and the signal-line driver circuit 106. The pixels 120, the scanning-line driver circuit 104, and the signal-line driver circuit 106 are encapsulated between and protected by the substrate 102 and the counter substrate. A plurality of terminals 108 formed with conductive films is provided over the substrate 102 and is connected to a connector 110 such as a flexible printed circuit (FPC) board. The terminals 108 are electrically connected to an external circuit, which is not illustrated, by the connector 110. A variety of signals and electronic power for displaying images are supplied from the external circuit to the scanning-line driver circuit 104 and signal-line driver circuit 106 via the connector 110 and the terminals 108. Note that either or both of the scanning-line driver circuit 104 and the signal-line driver circuit 106 may not be formed directly over the substrate 102, and a driver circuit formed over a substrate (such as a semiconductor substrate) different from the substrate 102 may be mounted over the substrate 102 and the connector 110.

### 2. Pixel Arrangement

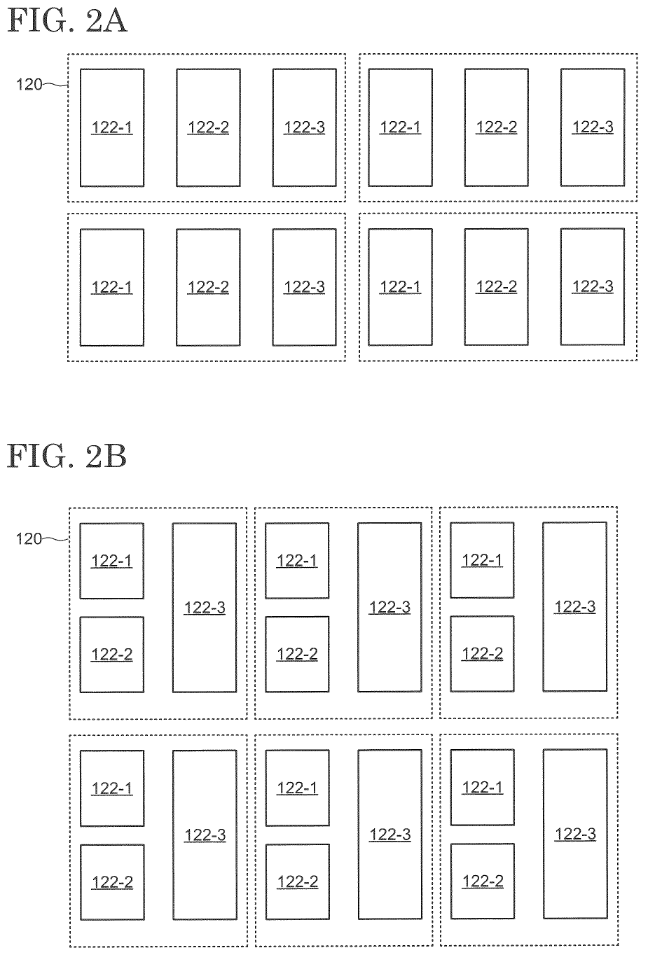

A schematic top view of a portion of the display region 112 of the display device 100 is shown in FIG. 2A. As shown in FIG. 2A, each pixel 120 is composed of a plurality of sub-pixels 122. Each sub-pixel 122 serves as the smallest unit providing color information. There is no restriction on the number of sub-pixels 122 in one pixel 120, but the number is typically 3. In the example shown in FIG. 2A, each sub-pixel 122 is composed of a first sub-pixel 122-1, a second sub-pixel 122-2, and a third sub-pixel 122-3 each including a pixel circuit (described below). The first sub-pixel 122-1, the second sub-pixel 122-2, and the third sub-pixel 122-3 are respectively provided with light-emitting elements providing the three primary colors, namely, a red-emissive light-emitting element, a green-emissive light-emitting element, and a blue-emissive light-emitting element. Signals to operate the pixel circuits are generated by the scanning-line driver circuit 104 and the signal-line driver circuit 106 on the basis of a variety of signals supplied from the external circuit. When the pixel circuits to which these signals are supplied are driven, the light-emitting elements connected to the pixel circuits emit light, enabling full-color display. Here, a red-emissive light-emitting element, a green-emissive light-emitting element, and a blue light-emitting elements are, for example, elements exhibiting an emission peak wavelength in a range equal to or longer than 650 nm and equal to or shorter than 750 nm, a range equal to or longer than 500 nm and equal to or shorter than 650 nm, and a range equal to or longer than 400 nm and equal to or shorter than 500 nm, respectively.

There is no restriction on the arrangement of the 120 pixels. For example, the stripe arrangement may be employed in which the first sub-pixel 122-1, the second sub-pixel 122-2, and the third sub-pixel 122-3 respectively providing red, green, and blue colors are sequentially arranged in a row direction, and in which the sub-pixels 122 providing the same emission color are arranged in the same column as shown in FIG. 2A. Alternatively, although not illustrated, a variety of arrangements such as the delta arrangement and the PenTile arrangement may be employed in addition to the mosaic arrangement in which the first sub-pixel 122-1, the second sub-pixel 122-2, and the third sub-pixel 122-3 are sequentially arranged in both the row direction and the column direction. Alternatively, the plurality of pixels 120 may be arranged so that one or a plurality of first sub-pixels 122-1 and one or a plurality of second sub-pixels 122-2 are sandwiched between adjacent third sub-pixels 122-3 as shown in FIG. 2B.

### 3. Structure of Light-Emitting Element

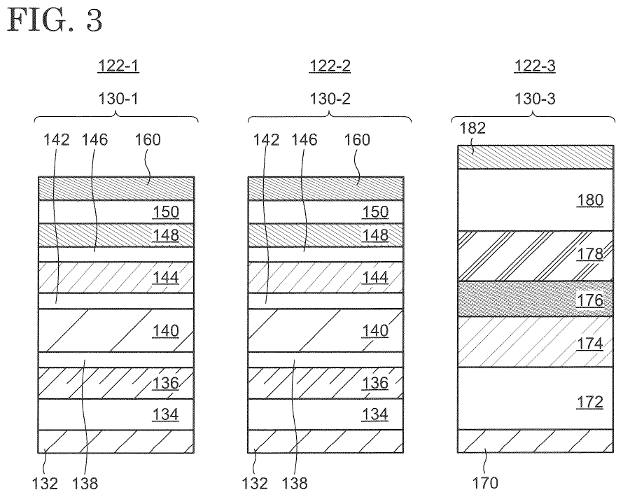

Schematic cross-sectional views of the red-emissive, green-emissive, and blue-emissive light-emitting elements respectively arranged in the first sub-pixel 122-1, the second sub-pixel 122-2, and the third sub-pixel 122-3 are shown in FIG. 3. The red-emissive light-emitting element 130-1 (hereinafter, referred to as a first light-emitting element) and the green-emissive light-emitting element 130-2 (hereinafter, referred to as a second light-emitting element) respectively disposed in the first sub-pixel 122-1 and the second sub-pixel 122-2 are each an organic electroluminescence element and each have a structure in which a plurality of functional layers containing one or a plurality of organic compounds is arranged between a pair of electrodes. On the other hand, the blue-emissive light-emitting element (hereinafter, referred to as a third light-emitting element) 130-3 disposed in the third sub-pixel 122-3 is an inorganic electroluminescence element and has a structure in which a plurality of semiconductor films each containing a first Group IIIB element (Group 13 element) and a first Group VB element (Group 15 element) is arranged between a pair of electrodes.

### 3-1. Organic Electroluminescence Element

Each of the first light-emitting element 130-1 and the second light-emitting element 130-2, which are each an organic electroluminescence element, has an anode 132 and a cathode 148 facing each other as a pair of electrodes as well as a plurality of functional layers therebetween. Examples of the functional layers include a hole-injection layer 134, a hole-transporting layer 136, an electron-blocking layer 138, an emission layer 140, a hole-blocking layer 142, an electron-transporting layer 144, an electron-injection layer 146, and the like. Each functional layer may have a single-layer structure or may be composed of a plurality of layers containing different materials. Each of the first light-emitting element 130-1 and the second light-emitting element 130-2 may include all of the aforementioned functional layers or only some of the functional layers. As an optional component, each of the first light-emitting element 130-1 and the second light-emitting element 130-2 may further include a cap layer 150 and/or a protective film 160 over the cathode 148. Hereinafter, the functional layers sandwiched between the anode 132 and the cathode 148 are also collectively referred to as an organic electroluminescence layer (organic EL layer).

Each functional layer is formed by applying a wet deposition method such as an inkjet method, a spin-coating method, a printing method, and a dip-coating method or a dry deposition method such as an evaporation method. When a potential difference is provided between the anode 132 and the cathode 148, holes and electrons are injected into the functional layers from the former and the latter, respectively, and the holes and electrons recombine within the emission layer 140. As a result, an excited state of an emission material contained in the emission layer 140 is formed. When the excited state relaxes to a ground state, light with a wavelength corresponding to the energy difference between the excited state and the ground state is emitted and can be observed as light emission from each luminescent element 130.

### (1) Anode and Cathode

The anode 132 injects holes to the organic EL layer and also functions as a reflective electrode to efficiently reflect the emission produced in the organic EL layer to the cathode 148 side. Therefore, the anode 132 may be formed using a metal with high reflectivity such as silver and aluminum or an alloy thereof. In addition, a film of a conductive oxide having a light-transmitting property may also be formed over the film containing these metals or alloys. As a conductive oxide, indium-tin oxide (ITO), indium-zinc oxide (IZO), and the like are represented. For example, a three-layer structure may be applied to the anode 132, which includes a layer containing a conductive oxide, a layer containing a metal such as silver and aluminum, and a layer containing a conductive oxide.

On the other hand, the cathode 148 injects electrons into the organic EL layer and also functions as a semi-transparent semi-reflective electrode which partly reflects and partly transmits the emission produced in the organic EL layer. A metal thin film including a metal such as aluminum, magnesium, and silver or an alloy thereof and having a thickness sufficient to transmit visible light may be used as the cathode 148. Alternatively, a conductive oxide having a light-transmitting property such as ITO and IZO may be used. When the aforementioned metal thin film is used as the cathode 148, a conductive oxide having a light-transmitting property may be stacked over the metal thin film. The cathode 148 is provided to be shared by the adjacent first light-emitting element 130-1 and the second light-emitting element 130-2. That is, it is provided to be continuous between the adjacent first sub-pixel 122-1 and second sub-pixel 122-2. However, as described below, the cathode 148 is provided so as not to overlap the third light-emitting element 130-3 and to expose at least a portion of the third sub-pixel 122-3 and the third light-emitting element 130-3.

The formation of the anode 132 and the cathode 148 in this manner allows a part of the light from the emission layer 140 to be repeatedly reflected between the anode 132 and the cathode 148 and to resonate. As a result, the emission intensity (i.e., emission efficiency) of the light-emitting element 130 can be increased in the frontal direction of the display device 100, and the narrowed emission can be extracted through the cathode 148. As a result, the color purity of the light-emitting element 130 is improved, and excellent color reproducibility can be provided to the display device 100. Specifically, the optical distance between the anode 132 and the cathode 148, the optical distance from the emission layer 140 corresponding to the emission region to the anode 132, and the optical distance from the emission layer 140 to the cathode 148 are adjusted so that each of the first light-emitting element 130-1 and the second light-emitting element 130-2 forms a microcavity. For example, in each of the first light-emitting element 130-1 and the second light-emitting element 130-2, the optical distance between the anode 132 and the cathode 148 is preferably adjusted to be equal to or greater than 80% and equal to or less than 120% of an integral multiple of half of the emission peak wavelength of the emission material in the emission layer 140. It is also preferable to adjust the optical distance from the anode 132 to the emission layer 140 and the optical distance from the cathode 148 to the emission layer 140 so as to be equal to or greater than 80% and equal to or less than 120% of an odd multiple of ¼ of the emission peak wavelength (one quarter wavelength) of the emission material. Note that an optical distance is the product of a thickness of a film and a refractive index of a material contained in the film. Therefore, the optical distance between the anode 132 and the cathode 148 is the summation of the products of the thickness and the refractive index of each functional layer.

The optical adjustment is performed by appropriately selecting the thickness of each functional layer included in the organic EL layer and the stacking structure thereof. For example, the optical distance between the anode 132 and the cathode 148, the optical distance from the anode 132 to the emission layer 140, and the optical distance from the cathode 148 to the emission layer 140 are adjusted by adjusting the thicknesses and number of layers of the hole-transporting layer 136 and the electron-transporting layer 144 as appropriate.

### (2) Hole-Injection Layer

The hole-injection layer 134 has a function of promoting hole injection from the anode 132 to the organic EL layer. A compound which is readily injected with holes, i.e., which is readily oxidized (electron-donating), can be used for the hole-injection layer 134. In other words, a compound with a shallow highest occupied molecular orbital (HOMO) level can be used. For example, an aromatic amine such as a benzidine derivative and a triarylamine, a carbazole derivative, a thiophene derivative, a phthalocyanine derivative such as copper phthalocyanine, and the like may be used. Alternatively, a polymeric material such as polythiophene, polyaniline, and their derivatives may be used, and poly(ethylenedioxythiophene)/poly(styrenesulfonic acid) is represented as an example. A mixture of the electron-donating compound such as the aromatic amine, the carbazole derivative described above, and an aromatic hydrocarbon with an electron acceptor may be used. Examples of the electron acceptors include a transition metal oxide such as vanadium oxide and molybdenum oxide, a nitrogen-containing heteroaromatic compound, and an aromatic compound with a strong electron-withdrawing group such as a cyano group.

### (3) Hole-Transporting Layer

The hole-transporting layer 136 has a function of transporting holes injected into the hole-injection layer 134 to the side of the emission layer 140, and a material the same as or similar to the material which can be used in the hole-injection layer 134 can be used. For example, a material with a deeper HOMO level than the hole-injection layer 134, but with a difference therebetween of approximately 0.5 eV or less can be used. Typically, an aromatic amine such as a benzidine derivative may be used.

### (4) Electron-Blocking Layer

The electron-blocking layer 138 has a function of confining electrons within the emission layer 140 by preventing the electrons injected from the cathode 148 from passing through the emission layer 140 and being injected into the hole-transporting layer 136 without contributing to recombination within the emission layer 140 as well as a function of preventing the excitation energy obtained in the emission layer 140 from undergoing energy transfer to the molecules in the hole-transporting layer described above. It is possible to prevent a decrease in emission efficiency by this mechanism.

For the electron-blocking layer 138, it is preferable to use a material having an electron-transporting property higher than or similar to a hole-transporting property and having a shallower lowest unoccupied molecular orbital (LUMO) level and a larger band gap than the molecules in the emission layer 140. Specifically, it is preferable to use a material having a triplet level higher than the emission material in the emission layer 140 by 0.2 eV or more, 0.3 eV or more, or 0.5 eV or more. Specifically, an aromatic amine derivative, a carbazole derivative, a 9,10-dihydroacridine derivative, a benzofuran derivative, a benzothiophene derivative, and the like are represented.

### (5) Emission Layer

The emission layer 140 has a so-called host-dopant structure and contains a host material and a dopant. As the host material, an oxadiazole derivative, a triazole derivative, a benzimidazole derivative, a quinoxaline derivative, a dibenzoquinoxaline derivative, a dibenzothiophene derivative, a dibenzofuran derivative, a pyrimidine derivative, a triazine derivative, a pyridine derivative, a bipyridine derivative, a phenanthroline derivative, an aromatic amine derivative, a carbazole derivative, and the like may be used in addition to a zinc or aluminum metal complex. The dopant functions as an emission material, and a phosphorescent material such as an iridium-based ortho-metal complex, a platinum porphyrin complex, and a rare earth complex may be used.

A red-emissive phosphorescent material is used in the first light-emitting element 130-1 arranged in the first sub-pixel 122-1. Specifically, an iridium complex having a pyrimidine skeleton such as (diisobutyrylmethanato)bis[4,6-bis(3-methylphenyl)pyrimidinato]iridium (III) and bis[4,6-bis(3-methylphenyl)pyrimidinato]pyrimidinato](dipivaloylmethanato) iridium (III), an iridium complex having a pyrazine skeleton such as (acetylacetonato)bis(2,3,5-triphenylpyrazinato) iridium (III) and bis(2,3,5-triphenylpyrazinato) (dipyvaloylmethanato) iridium (III), an iridium complex having a pyridine skeleton such as tris(1-phenylisoquinolinato-N,C2′) iridium (III) and bis(1-phenylisoquinolinato-N,C2′) iridium (III) may be used. Alternatively, a platinum complex such as 2,3,7,8,12,13,17,18-octaethyl-21H,23H-porphyrin platinum (II) or a rare earth metal complex such as tris(1,3-diphenyl-1,3-propanedionato) (monophenanthroline) europium (III) and tris[1-(2-tenoyl)-3,3,3-trifluoroacetonato](monophenanthroline) europium (III) may be used.

A green-emissive phosphorescent material is used in the second light-emitting element 130-2 arranged in the second sub-pixel 122-2. Specifically, a rare earth metal complex such as tris(acetylacetonato) (monophenanthroline) terbium (III) is represented in addition to an iridium complex having a pyrimidine skeleton such as tris(4-methyl-6-phenylpyrimidinato) iridium (III) and tris(4-t-butyl-6-phenylpyrimidinato) iridium (III), an iridium complex having a pyrazine skeleton such as (acetylacetonato)bis(3,5-dimethyl-2-phenylpyrazinato) iridium (III) and (acetylacetonato)bis(5-isopropyl-3-methyl-2-phenylpyrazinato) iridium (III), an iridium complex having a pyridine skeleton such as tris(2-phenylpyridinato-N,C2′) iridium (III) and bis(2-phenylpyridinato-N,C2′) iridium (III).

A thermally activated delayed fluorescence (TADF) material may be used instead of a phosphorescent material in the first light-emitting element 130-1 and/or the second light-emitting element 130-2. Here, delayed fluorescence refers to emission having a spectrum similar to that of normal fluorescence but with a significantly longer lifetime, and a lifetime thereof is 10⁻⁶ seconds or more, and preferably 10⁻³ seconds or more. As a thermally activated delayed fluorescent materials, a fullerene and its derivatives, an acridine derivative such as proflavine, eosin, and the like are represented, for example. In addition, a metal-containing porphyrin containing magnesium, zinc, cadmium, tin, platinum, indium, or palladium is represented. As a metal-containing porphyrin, a protoporphyrin-tin fluoride complex, a mesoporphyrin-tin fluoride complex, a hematoporphyrin-tin fluoride complex, a coproporphyrin tetramethyl ester-tin fluoride complex, an octaethylporphyrin-tin fluoride complex, an ethioporphyrin-tin fluoride complex, an octaethylporphyrin-platinum chloride complex, and the like are represented, for example. Furthermore, a heterocyclic compound having a TT-excessive heteroaromatic ring and a TT-deficient heteroaromatic ring such as 2-(biphenyl-4-yl)-4,6-bis(12-phenylindolo[2,3-a]carbazol-11-yl)-1,3,5-triazine may also be used.

### (6) Hole-Blocking Layer

The hole blocking layer 142 has a function of confining holes injected from the anode 132 within the emission layer 140 by preventing the holes from passing through the emission layer 140 and being injected into the electron-transporting layer 144 without contributing to recombination within the emission layer 140 as well as a function of preventing the excitation energy obtained in the emission layer 140 from undergoing energy transfer to the molecules in the electron-transporting layer 144. This mechanism prevents a decrease in emission efficiency.

For the hole-blocking layer 142, it is preferable to use a material having an electron-transporting property higher than or similar to a hole-transporting property and a deeper HOMO level and a larger band gap than the molecules in the emission layer 140. Specifically, the difference in the HOMO level between the molecules in the hole-blocking layer 142 and the molecules in the emission layer 140 is preferred to be 0.2 eV or more, 0.3 eV or more, or 0.5 eV or more. It is also preferable to use a material with a triplet level higher than the emission material by 0.2 eV or more, 0.3 eV or more, or 0.5 eV or more. Specifically, a phenanthroline derivative, an oxadiazole derivative, a triazole derivative, a metal complex with a relatively large band gap (e.g., 2.8 eV or higher) such as bis(2-methyl-8-quinolinolato) (4-hydroxy-biphenyl)aluminum, and the like are represented.

### (7) Electron-Transporting Layer

The electron-transporting layer 144 has a function of transporting electrons, which are injected from the cathode 148 through the electron-injection layer 146, to the emission layer 140. A compound (electron-accepting compound) which is readily reduced can be used for the electron-transporting layer 144. In other words, a compound with a shallow LUMO level can be used. For example, a metal complex containing a ligand with benzoquinolinol as a basic skeleton such as (8-quinolinolato) lithium, (tris(8-quinolinolato)aluminum, and tris(4-methyl-8-quinolinolato)aluminum, a metal complex containing a ligand with oxadiazole or thiazole as a basic skeleton, and the like are represented. Aluminum, lithium, zinc, and the like are represented as the central metal of the metal complex. In addition to these metal complexes, a triazine derivative, a hexaphenylbenzene derivative, a benzimidazole derivative, an azine derivative, an oxadiazole derivative, a thiazole derivative, a triazole derivative, and a compound with an electron-deficient heteroaromatic ring such a phenanthroline derivative may be used.

### (8) Electron-Injection Layer

A compound which promotes electron injection from the cathode 148 to the electron-transporting layer 144 may be used for the electron-injection layer 146. For example, a mixture of a compound which can be used in the electron-transporting layer 144 and an electron donor such as lithium and magnesium may be used. Alternatively, an inorganic compound such as lithium fluoride and calcium fluoride may be used.

### (9) Cap Layer

The cap layer 150 is provided to increase the emission efficiency of the light-emitting element 130 in the frontal direction of the display device 100 and to narrow the spectrum by forming a microcavity over the cathode 148 to allow the light extracted from the emission layer 140 through the cathode 148 to resonate again. Therefore, the cap layer 150 is preferably configured so that its optical distance is equal to or greater than 80% and equal to or less than 120% of an odd multiple of ¼ wavelength of the peak of the light obtained from the emission layer 140. The cap layer 150 may have a single-layer structure or may be composed of a plurality of layers.

A material with high transmittance in the visible light region is represented as the material included in the cap layer 150. Preferred materials are those which can be formed by an evaporation method, a spin-coating method, or an ink-jet method. An example of such a material is an organic compound. The organic compound may be the material contained in the functional layers, for example, or a polymer such as an acrylic resin, an epoxy resin, and a silicon resin. Alternatively, a polymeric material containing fluorine is represented. As a fluorine-containing polymeric material, polytetrafluoroethylene, poly(vinylidene fluoride), a derivative thereof, and a poly(vinyl ether) as well as a polyimide, a polymethacrylate, a polyacrylates, a polysiloxane, and the like with fluorine in the main or side chains are represented, for example. These polymers may be intramolecularly or intermolecularly cross-linked. Alternatively, an inorganic compound exemplified by a metal fluoride such as lithium fluoride, magnesium fluoride, and calcium fluoride may be included in place of an organic compound.

The cap layer 150 is continuous between the first light-emitting element 130-1 and the second light-emitting element, but the third sub-pixel 122-3 is exposed from the cap layer 150. The structure of the cap layer 150, i.e., the composition and the thickness thereof, may be the same or different between the first light-emitting element 130-1 and the second light-emitting element 130-2. The cap layer 150 with the same structure can be formed in the same process in the former case, enabling the formation of the display device 100 at a lower cost. In addition, since a difference in emission wavelength between the first light-emitting element 130-1 and the second light-emitting element 130-2 respectively providing red and green emission is smaller than a difference in emission wavelength between the first light-emitting element 130-1 and the third light-emitting element 130-3 respectively providing red and blue emission, a highly efficient microcavity can be fabricated even if the cap layer 150 with the same structure is formed so as to be shared by the first light-emitting element 130-1 and the second light-emitting element 130-2. Therefore, it is possible to improve color purity and increase emission efficiency without compromising the emission efficiency of the first light-emitting element 130-1 and the second light-emitting element 130-2, thereby improving the color reproducibility of the display device 100. When the structure of the cap layer 150 is different between the first light-emitting element 130-1 and the second light-emitting element 130-2, the cap layer 150 is configured so that the optical distance of the cap layer 150 of the first light-emitting element 130-1 is greater than that of the second light-emitting element 130-2. Hence, the cap layer 150 of the first light-emitting element 130-1 may be formed to have a multilayer structure, while the cap layer 150 of the second light-emitting element 130-2 may be formed to have a single-layer structure, for example.

### (10) Protective Film

The protective film 160 has a function of preventing impurities such as water and oxygen from entering the first light-emitting element 130-1 and the second light-emitting element 130-2 from the outside. One or a plurality of inorganic films containing a silicon-containing inorganic compound such as silicon nitride may be used as the protective film 160, for example. Alternatively, a structure may be employed in which an organic film containing a polymer such as an epoxy resin and an acrylic resin is sandwiched by inorganic films containing a silicon-containing inorganic compound. When the cap layer 150 is provided, the protective film 160 is provided over the cap layer 150 so as to be in contact with the cap layer 150. When the cap layer 150 is not provided, the protective film 160 may be provided over the cathode 148 so as to be in contact with the cathode 148.

### 3-2. Inorganic Electroluminescence Element

As shown in FIG. 3, the third light-emitting element 130-3, which is an inorganic electroluminescence element, has an anode 170 and a cathode 182 between which a plurality of inorganic semiconductor films each containing a first Group IIIB element (Group 13 element) and a first Group VB element (Group 15 element) is provided. The plurality of inorganic semiconductor films includes at least an emission layer 176 and an electron-transporting layer 178 and a hole-transporting layer 174 respectively located over and under the emission layer 176 and may further include a hole-injection layer 172 between the anode 170 and the hole-transporting layer 174 and an electron-injection layer 180 between the cathode 182 and the electron-transporting layer 178. The third light-emitting element 130-3 may have a protective film as an optional component. Hereinafter, the inorganic semiconductor films disposed between the anode 170 and the cathode 182 may be collectively referred to as an inorganic electroluminescence layer (inorganic EL layer).

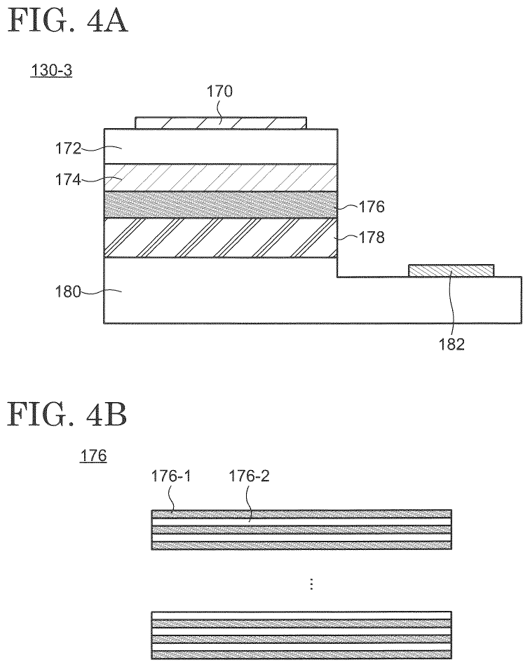

As shown in FIG. 3, the third light-emitting element 130-3 may be configured so that the anode 170 and the cathode 182 overlap each other in the vertical direction (normal direction of the substrate 102) and the inorganic EL layer is sandwiched by the anode 170 and the cathode 182. Alternatively, the anode 170 and cathode 182 may be arranged on the same side with respect to the inorganic EL layer as shown in FIG. 4A. In this case, the anode 170 and the cathode 182 do not overlap in the vertical direction, and the cathode 182 is placed over (on the anode 170 side) the electron-injection layer 180 (over the electron-transporting layer 178 when the electron-injection layer 180 is not provided). Moreover, the cathode 182 is exposed from the hole-injection layer 172, the hole-transporting layer 174, the emission layer 176, and the electron-transporting layer 178.

### (1) Anode and Cathode

The anode 170 and the cathode 182 are electrically connected to the inorganic EL layer and have a function of injecting holes and electrons into the inorganic EL layer, respectively. A thin film of a metal such as palladium, gold, silver, indium, and aluminum or an alloy thereof can be used as the anode 170 and the cathode 182 in addition to a light-transmitting conductive oxide such as ITO and IZO. The third light-emitting element 130-3 shown in FIG. 3 is configured so that the light obtained in the emission layer 176 is extracted from the cathode 182 side. Hence, it is preferred to use, as the cathode 182, a light-transmitting conductive oxide or a thin film of a metal or an alloy having a thickness which allows visible light to pass therethrough. For example, the cathode 182 may be a stack of a film containing a light-transmitting conductive oxide and a film partially covering this film and containing a metal such as gold. On the other hand, the anode 170 is preferably formed so as to include a metal in order to efficiently reflect the light from the emission layer 176. In contrast, in the third light-emitting element 130-3 shown in FIG. 4A, the light obtained in the emission layer 176 is extracted through the anode 170. Hence, the anode 170 contains a light-transmitting conductive oxide and is a stack of a film containing a light-transmitting conductive oxide and a film containing a metal such as gold, for example.

### (2) Inorganic EL Layer

The hole-injection layer 172, the hole-transporting layer 174, the emission layer 176, the electron-transporting layer 178, and the electron-injection layer 180 structuring the inorganic EL layer may each have a single-layer structure or a stacked-layer structure in which a plurality of films is stacked. As a semiconductor structuring these inorganic semiconductor films, a semiconductor which includes, for example, aluminum, gallium, and/or indium as well as nitrogen, phosphorus, and/or arsenic is represented. Typically, a gallium-based material is represented. For example, a gallium nitride-based material such as gallium nitride (GaN), aluminum gallium nitride (AlGaN), and indium gallium nitride (InGaN) and a gallium phosphide-based material such as gallium phosphide (GaP) and aluminum indium gallium phosphorus (AlGaInP) are represented. The inorganic semiconductor film may further contain a dopant. An element such as silicon, germanium, magnesium, zinc, cadmium, and beryllium is represented as a dopant. The addition of these elements enables valence electron control of each functional layer, by which not only can an intrinsic property (i-type) be maintained but also band gap control can be controlled, and p-type or n-type conductivity can be imparted.

In the hole-transporting layer 174 and the hole-injection layer 172, inorganic semiconductor films imparted with p-type conductivity are used, while inorganic semiconductor films imparted with n-type conductivity are used as the electron-injection layer 180 and the electron-transporting layer 178. For example, the electron-injection layer 180, the electron-transporting layer 178, the hole-transporting layer 174, and the hole-injection layer 172 may be configured to respectively include n-type gallium nitride, n-type aluminum gallium nitride, p-type aluminum gallium nitride, and p-type gallium nitride.

The emission layer 176 is configured to provide blue emission. More specifically, the emission layer 176 is configured to exhibit one or a plurality of emission peak wavelengths in the range equal or longer than 400 nm and equal to or shorter than 500 nm. For example, the emission layer 176 may be a single-layer structure of indium gallium nitride or may have a quantum well structure as schematically illustrated in FIG. 4B. A quantum well structure is a structure in which a plurality of thin films with different bandgaps and thicknesses ranging approximately from 1 to 6 nm is alternately stacked. That is, a plurality of high band-gap layers 176-1 and a plurality of low band-gap layers 176-2 are alternately stacked. Preferably, the high band gap layer 176-1 is provided in the uppermost layer and the lowermost layer. Examples of the quantum well structure include alternating layers of indium gallium nitride and gallium nitride, alternating layers of indium gallium phosphide arsenide phosphide (GaInAsP) and indium phosphide (InP), alternating layers of aluminum indium arsenide (AlInAs) and indium gallium arsenide (InGaAs), and the like. In the case of the alternating layers of indium gallium nitride and gallium nitride, the preferred composition of indium is equal to or less than 35 wt %.

The size of the third light-emitting element 130-3, i.e., the area of the inorganic EL layer in the plane parallel to the top surface of the substrate 102, may be determined appropriately considering the sizes of the pixel 120 and the sub-pixel 122. A preferred area of the inorganic EL layer is, for example, equal to or greater than 2×10² μm² and equal to or less than 2×10⁵ μm² or equal to or greater than 1×10³ μm² and equal to or less than 2×10⁵ μm². Alternatively, one side of the smallest rectangle surrounding the emission region is preferred to be equal to or greater than 15 μm and equal to or less than 150 μm or equal to or greater than 30 μm and equal to or less than 100 μm. Since each semiconductor film of the third light-emitting element 130-3 is formed using a chemical vapor deposition (CVD) method or the like, followed by performing an etching process, the peripheral portions of the semiconductor film are readily damaged by etching. Therefore, the contribution of the peripheral portions can be relatively reduced by fabricating the third light-emitting element 130-3 to have the aforementioned size. As a result, the decrease in emission efficiency caused by etching damage can be suppressed, which allows the third light-emitting element 130-3 to exhibit high emission efficiency.

### 4. Arrangement of Light-Emitting Elements

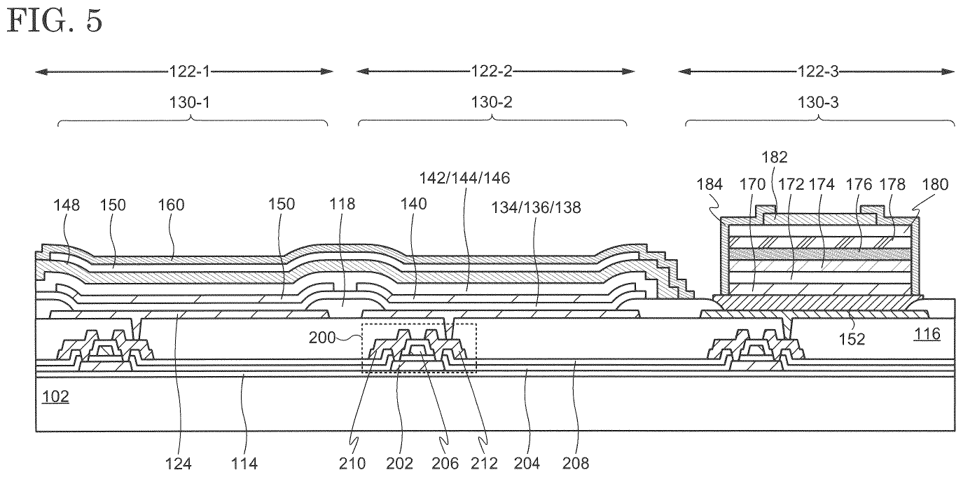

A schematic cross-sectional view of three sub-pixels 122 included in one pixel 120 is shown in FIG. 5. In the following schematic cross-sectional views including FIG. 5, some functional layers may not be illustrated for visibility. As described above, each sub-pixel 122 is provided with a pixel circuit as well as a pixel electrode 124 electrically connected to the pixel circuit. The structure of the pixel circuit may be arbitrarily determined, and the pixel circuit is configured by combining one or a plurality of transistors and one or a plurality of capacitance elements as appropriate. The pixel circuit of the third sub-pixel 122-3 provided with the third light-emitting element 130-3, which is an inorganic electroluminescence element, may have the same structure as or a different structure from the pixel circuit of the first sub-pixel 122-1 or the second sub-pixel 122-2.

There are no restrictions on the structure of the transistors provided in the pixel circuits, and a top-gate type transistor, a bottom-gate type transistor, or a transistor with a structure in which a channel is sandwiched between a pair of gate electrodes may be used. FIG. 5 shows a transistor 200 as one of the components of the pixel circuit. The transistor 200 is provided over the substrate 102 directly or through an undercoat 114 which is an optional component. The undercoat 114 is composed of one or a plurality of films containing a silicon-containing inorganic compound such as silicon nitride and silicon oxide. The transistor 200 is composed of a semiconductor film 202 structuring a channel, a gate insulating film 204 over the semiconductor film 202, a gate electrode 206 over the gate insulating film 204, an interlayer insulating film 208 over the gate electrode 206, terminals 210 and 212 located over the interlayer insulating film 208 and electrically connected to the semiconductor film 202, and the like.

A leveling film 116 is provided over the transistor 200 to absorb unevenness caused by the pixel circuit including the transistor 200 and to provide a flat surface. The pixel electrode 124 is electrically connected to the transistor 200 through an opening provided in the leveling film 116. The pixel electrode 124 may be connected to the terminal 212 of the transistor 200 directly or through a conductive film which is not illustrated. Over the pixel electrode 124, a partition wall 118 is provided covering an edge portion thereof, thereby separating adjacent light-emitting elements 130.

In the first light-emitting element 130-1 and the second light-emitting element 130-2, the pixel electrode 124 functions as the anode 132. Therefore, the first light-emitting elements130-1 and the second light-emitting element 130-2 are fabricated by sequentially forming the organic EL layer and the cathode 148 over the pixel electrode 124. The cathode 148 is connected to a first common wiring which is not illustrated and is applied with a constant potential.

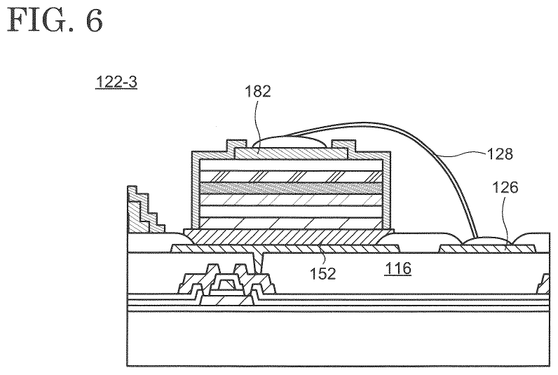

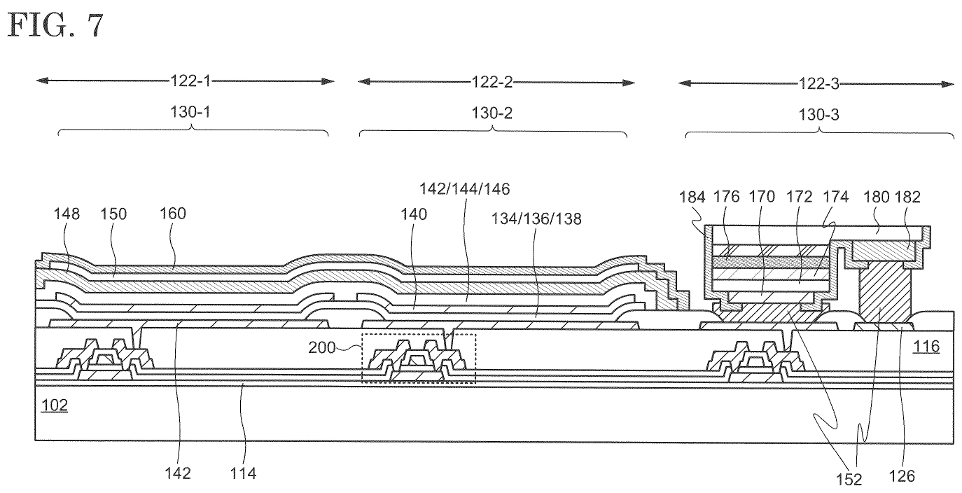

On the other hand, the third light-emitting element 130-3 separately fabricated over a substrate different from the substrate 102, such as a sapphire single crystal substrate, and including the anode 170, the inorganic EL layer, and the cathode 182 is connected to the pixel electrode 124 in the third sub-pixel 122-3. This connection is performed using a conductive adhesive 152 such as solder. In other words, the anode 170 of the third light-emitting element 130-3 is connected to the pixel circuit via the pixel electrode 124. As shown in FIG. 6, the cathode 182 of the third light-emitting element 130-3 is connected to a second common wiring 126 provided over the substrate and supplied with a constant potential. The first common wiring and the second common wiring 126 may be applied with the same potential or different potentials. As shown in FIG. 6, the connection between the cathode 148 and the second common wiring 126 may be performed with wire bonding using a conductive wire 128. When the anode 170 and the cathode 182 of the third light-emitting element 130-3 are located on the same side (FIG. 4A), the anode 170 and the cathode 182 may be respectively connected to the pixel electrode 124 and the second common wiring 126 via the adhesive 152 as shown in FIG. 7. Although not illustrated, the side on which the anode 170 and the cathode 182 are provided may be positioned on the opposite side to the substrate 102, and the anode 170 and the cathode 182 may be respectively connected to the pixel electrode 124 and the second common wiring 126 with wire bonding.

A protective film 184 which is an optional component is composed of one or a plurality of films containing a silicon-containing inorganic compound such as silicon nitride and silicon oxide. Alternatively, the protective film 184 may include boron nitride. As shown in FIG. 5 and FIG. 7, the protective film 184 may be provided so as to cover a portion of the anode 170 and/or a portion of the cathode 182. The protective film 184 is provided to further cover at least a portion of a side surface of the inorganic EL layer.

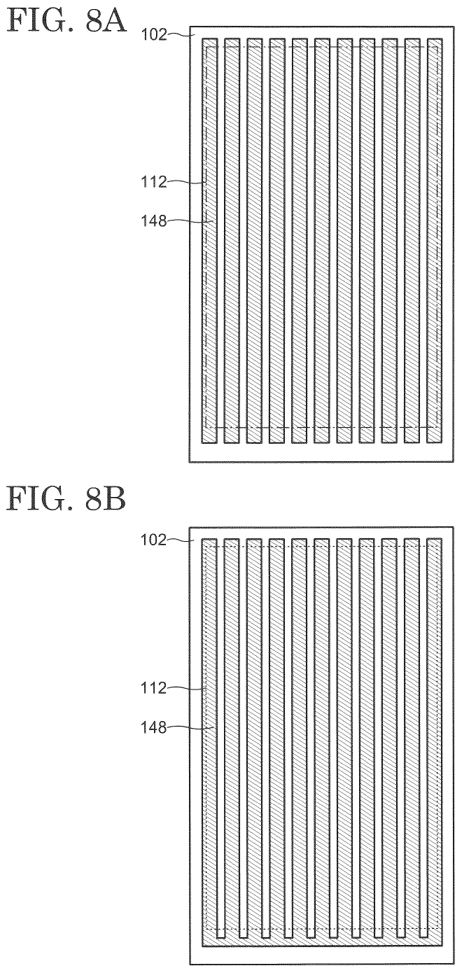

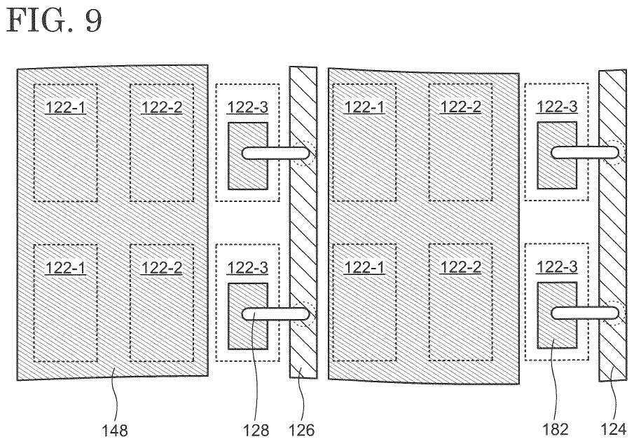

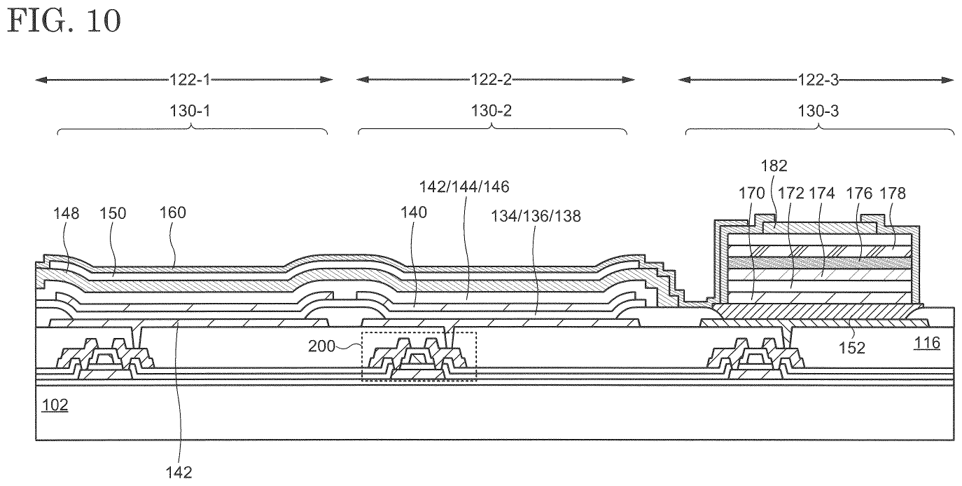

As described above, the cathode 148 is continuous between the adjacent first sub-pixel 122-1 and second sub-pixel 122-2 and is shared by the first light-emitting element 130-1 and the second light-emitting element 130-2 (see FIG. 5 and FIG. 7). Thus, the display device 100 has a plurality of cathodes 148 connected to the plurality of pixels 120 and arranged in a stripe shape or a comb shape as shown in FIG. 8A and FIG. 8B. On the other hand, since the third light-emitting element 130-3 is fabricated over a substrate different from the substrate 102 and then placed in the third sub-pixel 122-3, its cathode 182 is spaced away from the cathodes of the first light-emitting element 130-1 and the second light-emitting element 130-2 as shown in FIG. 5 and FIG. 9 which is a schematic top view thereof. When the first light-emitting element 130-1 and the second light-emitting element 130-2 are provided with the protective film 160 and the third light-emitting element 130-3 is also provided with the protective film 184, these protective films 160 and 184 may be spaced away from each other. Alternatively, the protective film 160 may cover a part of the protective film 184 as shown in FIG. 10.

As described above, red emission and green emission are respectively obtained from the first light-emitting element 130-1 and the second light-emitting element 130-2 respectively arranged in the first sub-pixel 122-1 and the second sub-pixel 122-2, while blue emission is obtained from the third light-emitting element 130-3 arranged in the third sub-pixel 122-3 in the display device 100. Since a material exhibiting phosphorescence or thermally activated delayed fluorescence is used in the first light-emitting element 130-1 and the second light-emitting element 130-2, it is possible to realize highly efficient emission. For example, the first light-emitting element 130-1 and the second light-emitting element 130-2 are capable of emitting light at current efficiencies exceeding 60 cd/A and 140 cd/A, respectively. On the other hand, since the third light-emitting element 130-3 is not an organic electroluminescence element having a low current efficiency but is an inorganic electroluminescence element, it is also possible to achieve a current efficiency exceeding 80 cd/A. Therefore, each pixel 120 is able to exhibit extremely high current efficiency, resulting in a significant reduction in power consumption of the display device 100. Furthermore, the amount of current supplied to each light-emitting element 130 can also be reduced, which enables the production of a display device having a long lifetime.

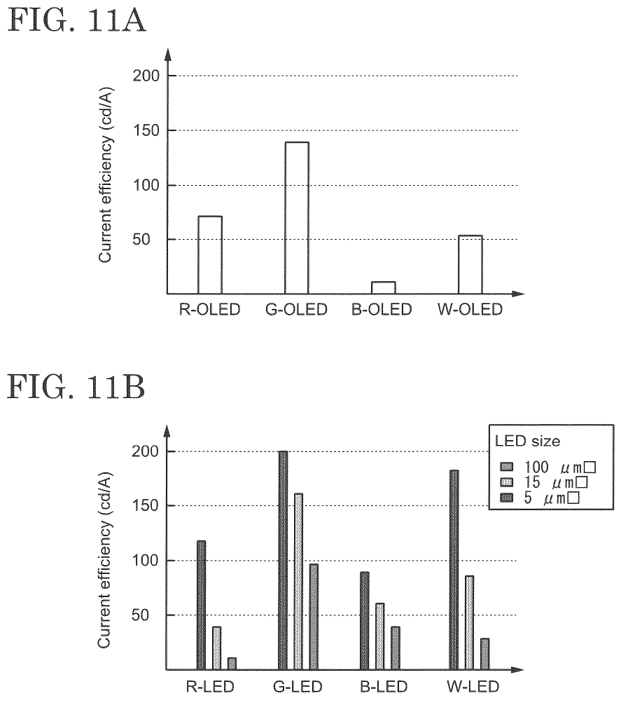

More specifically, when all of the light-emitting elements 130 are organic electroluminescence elements, an emission material exhibiting phosphorescence or thermally activated delayed fluorescence is used in the first light-emitting element 130-1 and the second and light-emitting element 130-2 which are respectively red- and green-emissive light-emitting elements. However, a fluorescence material is used in the third light-emitting element 130-3 which is a blue-emissive light-emitting element because it is difficult to fabricate a phosphorescence organic electroluminescence element providing blue emission with high color purity and having sufficient reliability. Therefore, the current efficiency of the third light-emitting element 130-3 is less than 10 cd/A. As a result, although high current efficiency is realized in the first light-emitting element 130-1 and the second light-emitting element 130-2, the current efficiency of the third light-emitting element 130-3 is extremely low, and the current efficiency of white emission obtained by turning on all of the light-emitting elements 130 remains approximately 50 cd/A as schematically shown in FIG. 11A.

On the other hand, when all of the light-emitting elements 130 are inorganic electroluminescence elements, high current efficiency can be obtained not only in the first light-emitting element 130-1 and the second light-emitting element 130-2 but also in the third light-emitting element 130-3 where the blue-emissive light-emitting element is arranged. However, a decrease in size of a light-emitting element causes a decrease in current efficiency due to the etching damage as described above. Therefore, when all of the light-emitting elements 130 are inorganic electroluminescence elements, the current efficiency may significantly decrease depending on the size of the light-emitting elements as schematically shown in FIG. 11B, which may inhibit the effective utilization of the high efficiency of inorganic electroluminescence elements.

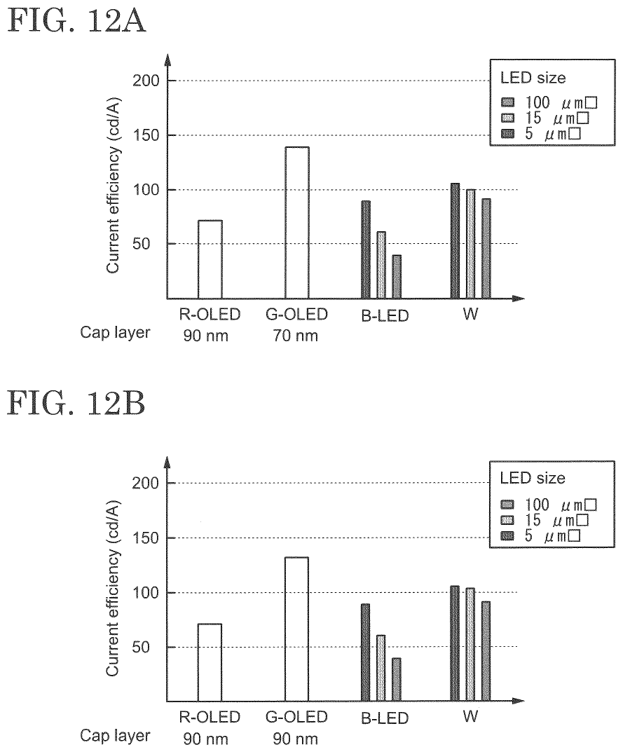

Here, it should be noted that there is almost no size dependence of current efficiency in organic electroluminescence elements. Therefore, high current efficiency can be obtained regardless of the size of the elements by respectively obtaining red and green emission from the organic electroluminescence elements in the first light-emitting element 130-1 and the second light-emitting element130-2 as in one of the embodiments of the present invention (See FIG. 12A). Moreover, although there is a dependence on the size of the element, it is still possible to realize an extremely high current efficiency compared with a blue-emissive organic electroluminescence element by obtaining the blue emission in the third light-emitting element 130-3. Therefore, high current efficiency can be obtained from all of the light-emitting elements 130, and it is also possible to obtain white light emission with a current efficiency of around 100 cd/A.

As described above, a microcavity with high efficiency can also be formed in both elements even if the microcavity is fabricated by forming the cap layer 150 which is continuous between the first light-emitting element 130-1 and the second light-emitting element and 130-2 and which has the same structure (see FIG. 5 and FIG. 7). Thus, even if the thickness of the cap layer 150 is identical between the first light-emitting element 130-1 and the second light-emitting element 130-2, it is possible to obtain a current efficiency comparable to the case (FIG. 12A) using the cap layers 150 respectively having optimized thicknesses for the first light-emitting element 130-1 and the second light-emitting element 130-2 (FIG. 12B). Therefore, implementation of an embodiment of the present invention enables the production of a display device with high efficiency while reducing the number of formation processes of the cap layer 150. This feature contributes to reducing the manufacturing cost of the display device 100.

### 5. Manufacturing Method of Display Device

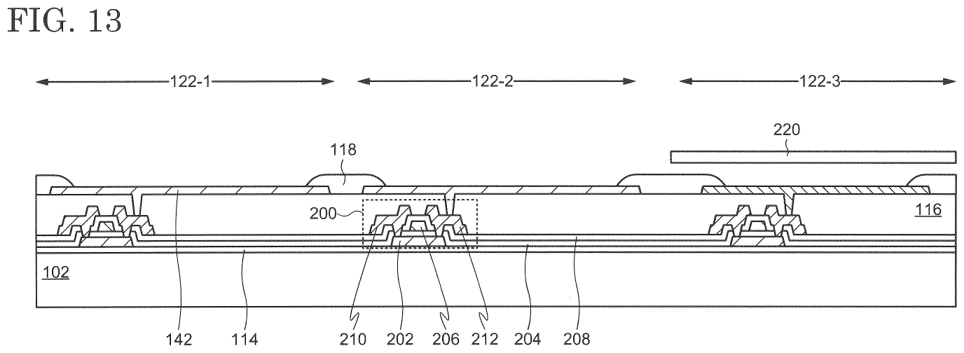

Hereinafter, an example of a manufacturing method of the display device 100 is explained using FIG. 13 through FIG. 19. Similar to FIG. 5 and the like, some functional layers may not be illustrated.

First, the plurality of pixels 120 is formed over the substrate 102 (FIG. 13). Since the processes up to this step can be performed by combining known methods and materials as appropriate, an explanation is omitted.

### (1) Formation of Organic Electroluminescence Elements

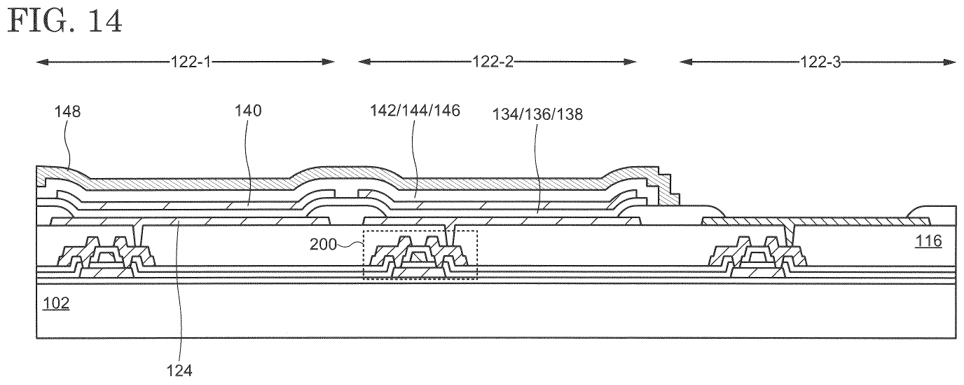

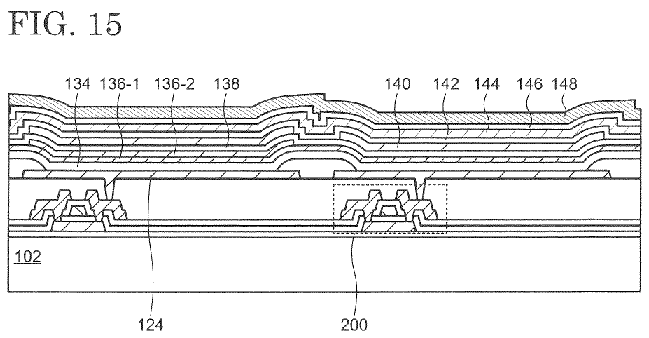

Next, the first light-emitting element 130-1 and the second light-emitting element 130-2, which are organic electroluminescence elements, are fabricated. Specifically, a deposition mask (metal mask) 220 is placed over the substrate 102 to expose the first sub-pixel 122-1 and the second sub-pixel 122-2 and cover the third sub-pixel 122-3 (FIG. 13). At this time, the partition wall 118 and the deposition mask 220 may be in contact with each other. In this state, the functional layers structuring the organic EL layer and the cathode 148 are sequentially formed using an evaporation method (FIG. 14). When the structures and the materials of the functional layers differ between the first light-emitting element 130-1 and the second light-emitting element 130-2, masks for pixel-by-pixel coating (an evaporation mask covering one of the first sub-pixel 122-1 and the second sub-pixel 122-2 and the third sub-pixel 122-3 and an evaporation mask covering the other of the first sub-pixel 122-1 and the second sub-pixel 122-2 and the third sub-pixel 122-3) are used as appropriate to fabricate the functional layers in each sub-pixel 122. For example, the emission layers 140 are separately formed in the sub-pixels 122 because at least the emission materials contained in the emission layers 140 are different between the first light-emitting element 130-1 and the second light-emitting element 130-2. The optical distance of the organic EL layer to form an appropriate microcavity in the first light-emitting element 130-1 with a longer emission wavelength is larger than that in the second light-emitting element 130-2. Therefore, as shown in FIG. 15, a first hole-transporting layer 136-1 which is shared by the first light-emitting element 130-1 and the second light-emitting element 130-2 may be prepared using an evaporation mask exposing the first sub-pixel 122-1 and the second sub-pixel 122-2, and then a second hole-transporting layer 136-2 may formed over the first hole-transporting layer 136-1 using a mask for pixel-by-pixel coating exposing only the first sub-pixel 122-1, for example. Although a detailed explanation is omitted, the electron-transporting layer 144 may also be composed of a first electron-transporting layer shared by the first light-emitting element 130-1 and the second light-emitting element 130-2 and a second electron-transporting layer selectively provided only in the first light-emitting element 130-1.

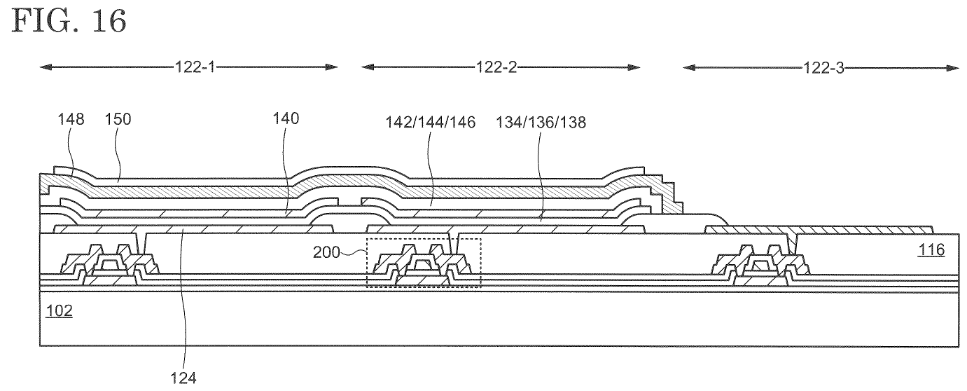

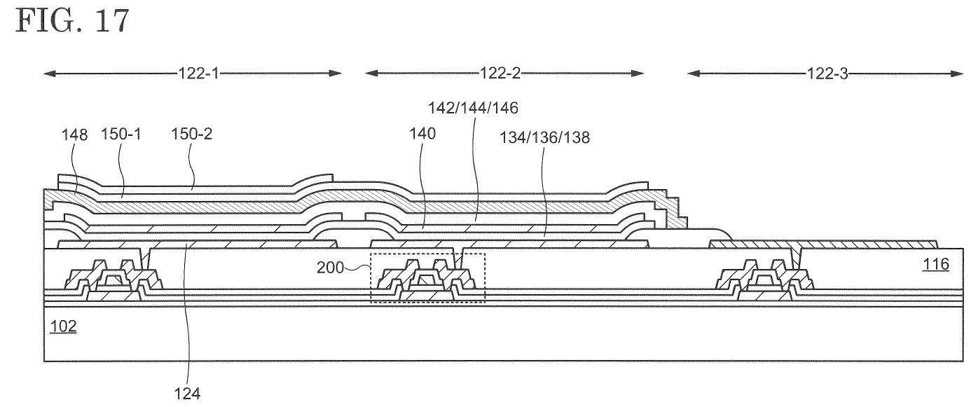

When the cap layer 150 is formed, evaporation masks are used as appropriate to prepare the cap layer 150 over the cathode 148 by applying an evaporation method (FIG. 16), similar to the functional layers. When the structure (thickness and composition) of the cap layer 150 is the same between the first light-emitting element 130-1 and the second light-emitting element 130-2, the cap layer 150 continuous between the first light-emitting elements 130-1 and the second light-emitting element 130-2 may be prepared in a single evaporation process. When the thickness of the cap layer 150 is different between the first light-emitting element 130-1 and the second light-emitting element 130-2, a first cap layer 150-1 continuous between the first light-emitting element 130-1 and the second light-emitting element 130-2 and having the same thickness between the first light-emitting element 130-1 and the second light-emitting element 130-2 is formed as shown in FIG. 17. Then, a mask for pixel-by-pixel coating selectively exposing the first light-emitting element 130-1 with a longer emission wavelength is used to form a second cap layer 150-2 in the first sub-pixel 122-1 by applying an evaporation method.

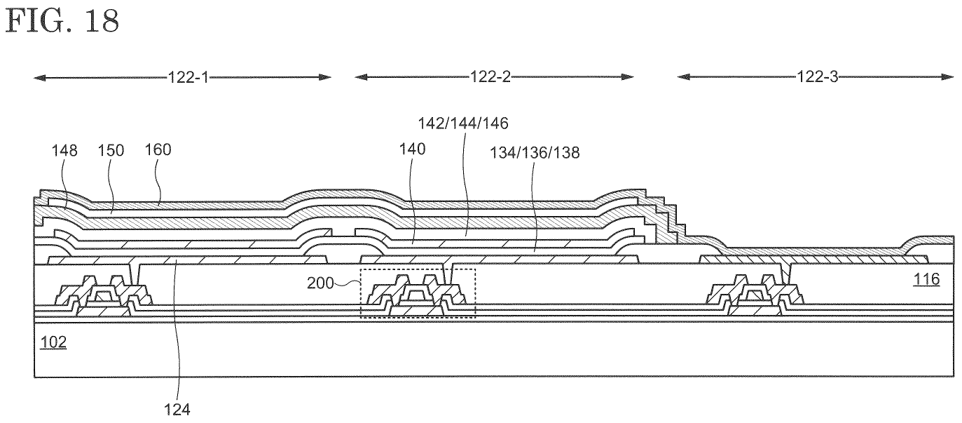

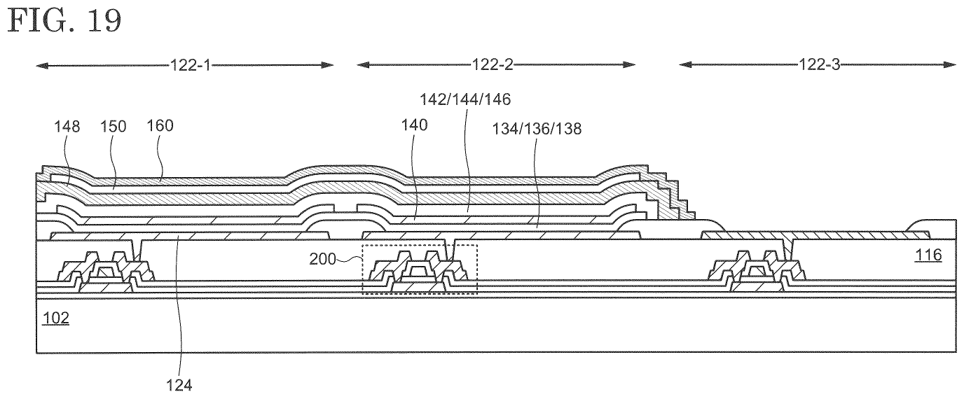

When the protective film 160 is formed, a film of silicon nitride or silicon oxide or a stack thereof may be formed over the cathode 148 or the cap layer 150 using a CVD method, for example. At this time, the protective film 160 may also be formed over the third sub-pixel 122-3 as shown in FIG. 18, and then the protective film 160 may be etched to expose the pixel electrode 124 of the third sub-pixel 122-3 (FIG. 19).

### (2) Formation of Inorganic Electroluminescence Element

After that, the third light-emitting element 130-3 is arranged in the third sub-pixel 122-3. As described above, the third light-emitting element 130-3 may be arranged by connecting the anode 170 to the pixel electrode 124 using the conductive adhesive 152 and connecting the cathode 182 to the second common wiring 126 with wire bonding. Alternatively, the anode 170 and the cathode 182 may be respectively connected to the pixel electrode 124 and the second common wiring 126 with wire bonding. The inorganic EL layer of the third light-emitting element 130-3 is preferably formed by a metal-organic vapor deposition method or molecular beam epitaxy.

By the above processes, the display device 100 shown in FIG. 5 can be manufactured. In these processes, the first light-emitting element 130-1 and the second light-emitting element 130-2 are formed prior to the third light-emitting element 130-3. Therefore, the evaporation masks 220 and the masks for pixel-by-pixel coating can be placed near the substrate 102 (e.g., so as to be in contact with the partition wall 118) to form the functional layers, which prevents the vaporized organic compound from entering a gap between the evaporation mask 220 and the substrate 102 during evaporation. Therefore, the functional layers can be more precisely arranged.

### (3) Modified Example

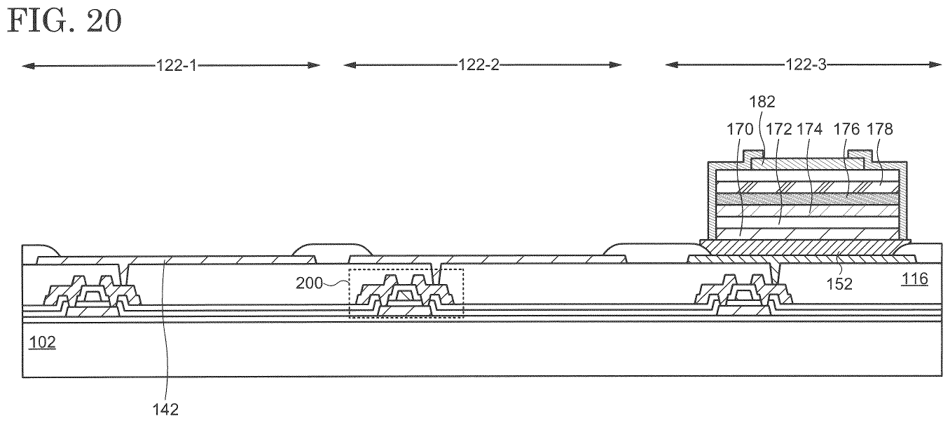

The manufacturing method of the display device 100 is not limited thereto, and the third light-emitting element 130-3 which is an inorganic electroluminescence element may be first arranged in the third sub-pixel 122-3 (FIG. 20), and then the first light-emitting element 130-1 and the second light-emitting element 130-2, which are organic electroluminescence elements, may be arranged. In this modified example, it is possible to completely eliminate the influence of heat used during wire bonding on the first light-emitting element 130-1 and the second light-emitting element 130-2.

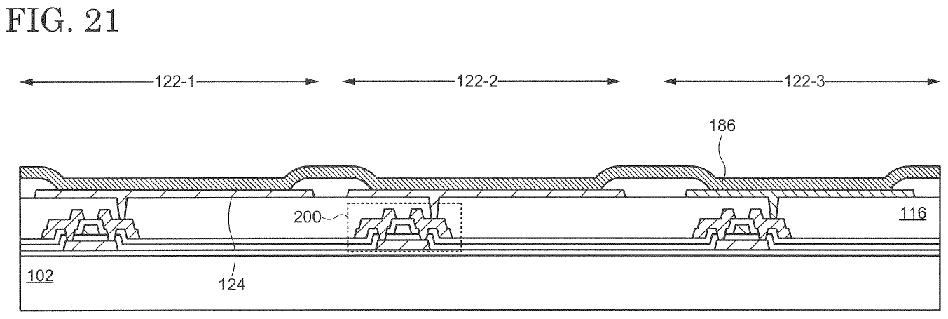

In addition, the fabrication method of the third light-emitting element 130-3 which is an inorganic electroluminescence element is not limited to the method described above. Specifically, instead of arranging the third light-emitting element 130-3, which is fabricated on a substrate different from the substrate 102 and has the anode 170 and the cathode 182, in the third sub-pixel 122-3, the third light-emitting element 130-3 may be fabricated by forming the inorganic EL layer and the cathode 182 over the substrate 102 with a sputtering method. In this case, the pixel electrode 124 is caused to serve as the anode 170, and a buffer layer 186 is formed thereover by a CVD method or a sputtering method, for example (FIG. 21). The buffer layer 186 is a configuration contributing to the promotion of crystallization of the inorganic EL layer provided thereover, and the generation of crystal defects in the inorganic EL layer can be effectively suppressed by forming the inorganic EL layer over the buffer layer 186. Since conductivity is also required for the buffer layer 186, the buffer layer 186 may be fabricated using a conductive metal nitride such as indium aluminum nitride, titanium nitride, gallium nitride, and aluminum nitride, a semiconductor such as silicon and germanium, or a metal such as titanium, aluminum, silver, nickel, copper, strontium, rhodium, palladium, iridium, platinum, and gold. If necessary, annealing may be performed on the buffer layer 186 to promote crystallization. Note that, when the pixel electrode 124 has a function to promote crystallization of the inorganic EL layer, the inorganic EL layer may be formed directly over the pixel electrode 124 without providing the buffer layer 186.

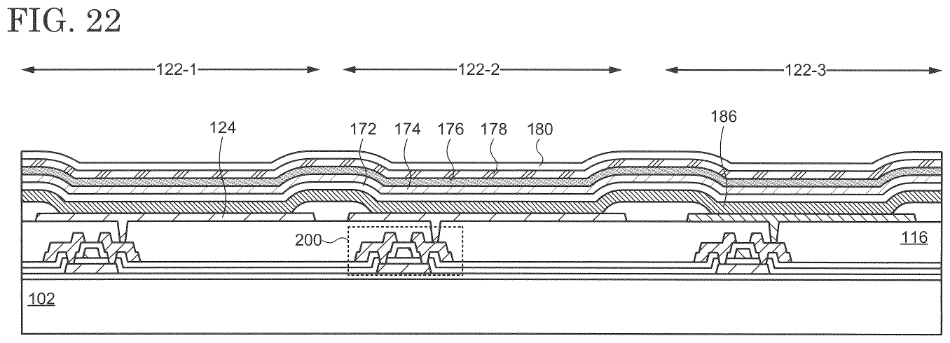

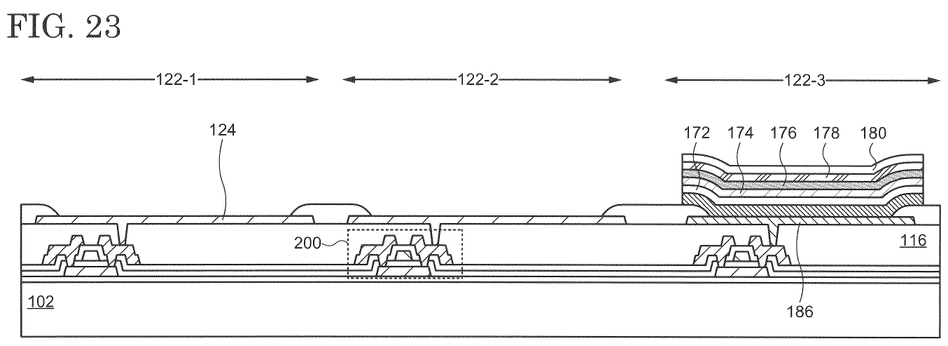

Next, the semiconductor films structuring the inorganic EL layer such as the hole-injection layer 172, the hole-transporting layer 174, the emission layer 176, the electron-transporting layer 178, and the electron-injection layer 180 are sequentially formed over buffer layer 186 with a sputtering method (FIG. 22). Note that the buffer layer 186 and the inorganic EL layer may be selectively formed over the third sub-pixel 122-3, or may be formed over all of the sub-pixels 122 as shown in FIG. 22 and then these components may be removed by etching in the first sub-pixel 122-1 and the second sub-pixel 122-2 (FIG. 23).

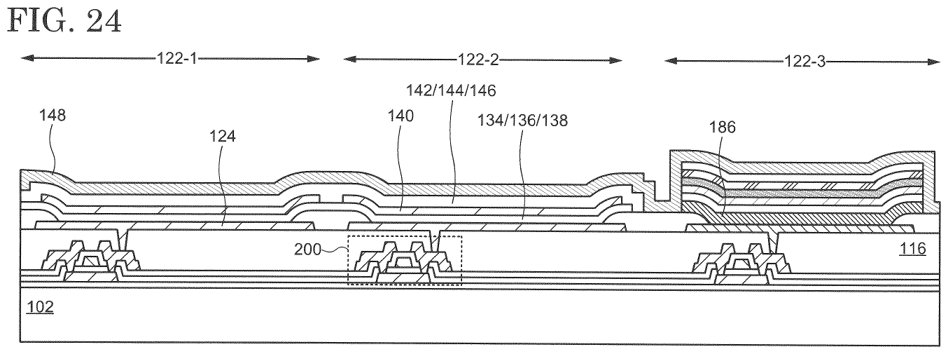

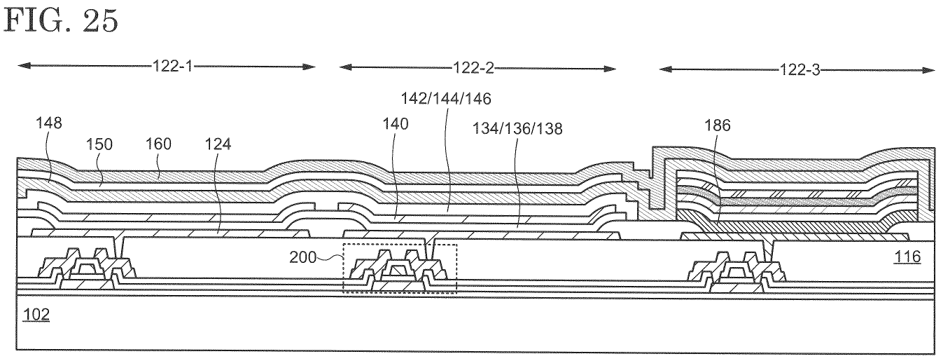

Then, the first light-emitting element 130-1 and the second light-emitting element 130-2 are respectively formed in the first sub-pixels 122-1 and the second sub-pixels 122-2 using the aforementioned method. At this time, the cathode 148 may be formed so as to be shared by all of the sub-pixels 122 as shown in FIG. 24. Thus, when this manufacturing method is applied, the cathode 148 is continuous over all of the sub-pixels 122 and exists in the same layer. After that, the cap layer 150 and the protective film 160 may be formed according to the method described above, if necessary (FIG. 25). The protective film 160 may also be formed so as to be continuous over all of the sub-pixels 122 and exist in the same layer.

As described above, in the display device 100 according to an embodiment of the present invention, red- and green-emissive organic electroluminescence elements and the blue-emissive inorganic electroluminescence element are provided in the sub-pixels 122, and the three primary colors of light are produced by these light-emitting elements to express display functions. Hence, the extremely high emission efficiency provided by these light-emitting elements can be used in each of the 122 sub-pixels. Therefore, implementation of an embodiment of the present invention allows the production of a display device 100 with high efficiency and low power consumption.

The aforementioned modes described as the embodiments of the present invention can be implemented by appropriately combining with each other as long as no contradiction is caused. Furthermore, any mode which is realized by persons ordinarily skilled in the art through the appropriate addition, deletion, or design change of elements or through the addition, deletion, or condition change of a process on the basis of the display device according to each embodiment is included in the scope of the present invention as long as they possess the concept of the present invention.

It is understood that another effect different from that provided by each of the aforementioned embodiments is achieved by the present invention if the effect is obvious from the description in the specification or readily conceived by persons ordinarily skilled in the art.

What is claimed is:

1. A display device comprising at least one pixel comprising a first sub-pixel, a second sub-pixel, and a third sub-pixel,
wherein the first sub-pixel and the second sub-pixel respectively comprise red-emissive and green-emissive organic electroluminescence elements,
the third sub-pixel comprises a blue-emissive inorganic electroluminescence element,
each of the organic electroluminescence elements comprises an anode, a cathode, and an organic electroluminescence layer between the anode and the cathode, and
the inorganic electroluminescence element comprises an anode, a cathode, and an inorganic electroluminescence layer electrically connected to the anode and the cathode.

2. The display device according to claim 1,
wherein the organic electroluminescence layer contains a phosphorescence material or a thermally activated delayed fluorescence material.

3. The display device according to claim 1,
wherein the inorganic electroluminescence layer contains a gallium nitride-based material.

4. The display device according to claim 1,
wherein the inorganic electroluminescence layer comprises:
a hole-injection layer over the anode,
a hole-transporting layer over the hole-injection layer;
an emission layer over the hole-transporting layer;
an electron-transporting layer over the emission layer; and
an electron-injection layer over the electron-transporting layer, and
the cathode is located over the electron-injection layer.

5. The display device according to claim 1,
wherein the inorganic electroluminescence layer comprises:
a hole-injection layer over the anode;
a hole-transporting layer over the hole-injection layer;
an emission layer over the hole-transporting layer;
an electron-transporting layer over the emission layer; and
an electron-injection layer over the electron-transporting layer, and
the cathode is located under the electron-injection layer and is exposed from the hole-injection layer, the hole-transporting layer, the emission layer, and the electron-transporting layer in a vertical direction.

6. The display device according to claim 1,
wherein each of the organic electroluminescence elements further comprises a cap layer over the cathode, and
the cap layers have the same structure between the organic electroluminescence elements of the first sub-pixel and the second sub-pixel.

7. The display device according to claim 1,
wherein each of the organic electroluminescence elements further comprises a cap layer over the cathode, and
the cap layers are different in thickness between the organic electroluminescence elements of the first sub-pixel and the second sub-pixel.

8. The display device according to claim 1,
wherein each of the organic electroluminescence elements further comprises a protective film over the cathode.

9. The display device according to claim 1,
wherein the cathodes of the organic electroluminescence elements continue between the first sub-pixel and the second sub-pixel, and
the inorganic electroluminescence element is exposed from the cathodes.

10. The display device according to claim 1,
wherein the at least one pixel includes a plurality of pixels, and
the cathodes of the organic electroluminescence elements are formed in a stripe shape or a comb shape.

11. The display device according to claim 1,
wherein an area of the inorganic electroluminescence element is equal to or greater than 2×10² μm² and equal to or less than 2×10⁵ μm².

12. The display device according to claim 1,
wherein the first sub-pixel, the second sub-pixel, and the third sub-pixel each have a pixel circuit and a pixel electrode electrically connected to the pixel circuit,
the pixel circuit serves as the anode in the first sub-pixel and the second sub-pixel, and
the anode of the inorganic electroluminescence element is electrically connected to the pixel circuit through the pixel electrode.

13. A manufacturing method of a display device comprising:
forming at least one pixel comprising a first sub-pixel, a second sub-pixel, and a third sub-pixel;
respectively forming red-emissive and a green-emissive organic electroluminescence elements in the first sub-pixel and the second sub-pixel; and
forming a blue-emissive inorganic electroluminescence element in the third sub-pixel,
wherein each of the organic electroluminescence elements comprises an anode, a cathode, and an organic electroluminescence layer between the anode and the cathode, and
the inorganic electroluminescence element comprises an anode, a cathode, and an inorganic electroluminescence layer electrically connected to the anode and the cathode.

14. The manufacturing method according to claim 13,
wherein the organic electroluminescence layer contains a phosphorescence material or a thermally activated delayed fluorescence material.

15. The manufacturing method according to claim 13,
wherein the inorganic electroluminescence layer contains a gallium nitride-based material.

16. The manufacturing method according to claim 13,
wherein each of the first sub-pixel, the second sub-pixel, and the third sub-pixel comprises a pixel circuit and a pixel electrode electrically connected to the pixel circuit, and
the inorganic electroluminescence element is formed by electrically connecting the anode to the pixel electrode.

17. The manufacturing method according to claim 13,
wherein each of the first sub-pixel, the second sub-pixel, and the third sub-pixel comprises a pixel circuit and a pixel electrode electrically connected to the pixel circuit, and
the organic electroluminescence element is formed by stacking the organic electroluminescence layer and the cathode over the pixel electrode using the pixel electrode as the anode.

18. The manufacturing method according to claim 13,
wherein the inorganic electroluminescence element is formed after forming the organic electroluminescence element.

19. The manufacturing method according to claim 13,
wherein the cathodes of the organic electroluminescence elements are formed so that the cathodes continue between the first sub-pixel and the second sub-pixel, and the inorganic electroluminescence element is exposed from the cathodes.

20. The manufacturing method according to claim 13,
wherein the at least one pixel includes a plurality of pixels, and
the cathodes of the organic electroluminescence elements are formed in a stripe shape or a comb shape.
